(19) United States
(12) Patent Application Publication
(10) Pub. No.: US 2025/0324820 A1
(43) Pub. Date: Oct. 16, 2025

(54) QUANTUM LIGHT SOURCE WITH DUAL OPTICAL CAVITIES

(71) Applicants: THE REGENTS OF THE UNIVERSITY OF COLORADO, A BODY CORPORATE, Denver, CO (US); GOVERNMENT OF THE UNITED STATES OF AMERICA, AS REPRESENTED BY THE SECRETARY OF COMMERCE, GAITHERSBURG, MD (US)

(72) Inventors: Poolad IMANY, Boulder, CO (US); Kevin L. SILVERMAN, Longmont, CO (US); Ryan A. DECRESCENT, Boulder, CO (US); Zixuan WANG, Boulder, CO (US); Robert BOUTELLE, Superior, CO (US); Richard MIRIN, Boulder, CO (US)

(21) Appl. No.: 18/862,848

(22) PCT Filed: May 5, 2023
(86) PCT No.: PCT/US2023/021226

§ 371 Date: Nov. 4, 2024

Related U.S. Application Data
(60) Provisional application No. 63/364,231, filed on May 5, 2022.

(51) Int. Cl. H10H 20/812; G02B 6/34; H10H 20/814; H10H 20/851; H10H 20/856

(52) U.S. Cl. CPC H10H 20/812; G02B 6/34; H10H 20/8142; H10H 20/8512; H10H 20/856

(57) ABSTRACT

A quantum light source includes a quantum emitter located within both a bullseye cavity and a Fabry-Perot cavity. The Fabry-Perot cavity is formed from first and second mirrors that face each other to define an optical axis extending therebetween. The bullseye cavity lies in a plane perpendicular to the optical axis and in between the first and second mirrors. The quantum emitter may be a quantum dot, a point defect in a crystal (e.g., nitrogen-vacancy center in diamond), an atom, or another type of quantum system. Spontaneous emission from the quantum emitter is strongly coupled into a mode of the Fabry-Perot cavity while the bullseye cavity uses destructive interference to prevent emission of photons along directions transverse to the axis of the Fabry-Perot cavity. Light leaks out of the Fabry-Perot cavity into a well-defined traveling-wave mode that can be efficiently coupled to an optical fiber.

### RELATED APPLICATIONS

This application claims priority to U.S. Provisional Patent Application No. 63/364,231, filed on May 5, 2022, the entirety of which is incorporated herein by reference.

### STATEMENT REGARDING FEDERALLY SPONSORED RESEARCH OR DEVELOPMENT

This invention was made with government support under grant number 70NANB18H006, awarded by the National Institute of Standards and Technology (NIST). The government has certain rights in the invention.

### BACKGROUND

Single-photon sources that produce individual photons on demand are used in many quantum technologies, such as quantum random number generation, quantum key distribution, and quantum metrology.

### SUMMARY

A quantum light source includes a bullseye cavity, a Fabry-Perot cavity, and a quantum emitter located within both the bullseye cavity and the Fabry-Perot cavity. The Fabry-Perot cavity is formed from first and second mirrors that face each other to define an optical axis extending therebetween. The bullseye cavity is formed from a center disk within which the quantum emitter is embedded. The bullseye cavity also includes a sequence of concentric rings, with alternating refractive indices, surrounding the center disk. The bullseye cavity lies in a plane perpendicular to the optical axis and in between the first and second mirrors. The quantum emitter may be a quantum dot (e.g., InAs, GaAs, etc.), a point defect in a crystal (e.g., nitrogen-vacancy center in diamond, silicon-vacancy center in diamond, carbon-anti-site-vacancy in silicon carbide, etc.), a trapped atom or molecule, a trapped ion, or another type of quantum system that spontaneously decays when excited (e.g., pumped optically or electrically).

The quantum emitter is positioned such that its spontaneous emission is strongly coupled to a mode of the Fabry-Perot cavity. The bullseye cavity uses destructive interference to inhibit spontaneous emission from the quantum emitter along directions transverse to the axis of the Fabry-Perot cavity. That is, the bullseye cavity enhances spontaneous emission in the directions along the axis of the Fabry-Perot cavity, thereby increasing the coupling into the mode of the Fabry-Perot cavity. Light in this mode leaks out the Fabry-Perot cavity, via the first or second mirror, and into a well-defined traveling-wave mode with a Gaussian transverse intensity profile that can be efficiently coupled to an optical fiber. Since the quantum emitter is located inside a cavity, the spontaneous decay rate of the quantum emitter is increased by the Purcell effect (as compared to its spontaneous decay rate in free space).

Advantageously, the quantum light source of the present embodiments is more efficient than prior-art quantum light sources that use only a Fabry-Perot cavity or bullseye cavity. The efficiency of a light source quantifies how much spontaneous emission from the quantum emitter can be utilized for the application at hand. The efficiency incorporates not only the fraction of the spontaneous emission that is collected (as opposed to being lost to the surrounding environment), but also losses from coupling the spontaneous emission into an optical fiber, losses from transmission along the optical fiber, and losses from coupling the light out of the optical fiber. One factor that reduces the efficiency of a light source is the fact that quantum emitters typically emit uniformly in free space. In this case, collecting all of the spontaneous emission and redirecting it into one direction is challenging with conventional optics (e.g., lenses and mirrors). An alternative approach is to modify the emission profile by placing the quantum emitter inside an optical cavity, which preferentially couples the spontaneous emission into a mode of the cavity.

The higher efficiencies that can be achieved with the present embodiments will improve many applications that use quantum light. One such application is quantum random number generation. In this case, the quantum light source of the present embodiments can be operated as a single photon source. Due to the combination of a bullseye cavity and a Fabry-Perot cavity, this single-photon source can achieve efficiencies exceeding 75%. By comparison, the highest efficiency demonstrated by a prior-art single-photon source is only 57%. As described in more detail below, the higher efficiency that can be achieved with the present embodiments surpasses the threshold for generating private randomness with low bias through quantum routing and the laws of quantum mechanics (e.g., superposition and entanglement).

In addition to a single-photon source, the quantum light source of the present embodiments can be configured to generate other types of quantum light, such as n-photon states (i.e., Fock states of n photons), entangled photons (e.g., entangled pairs), and cluster states. Accordingly, other applications that can benefit from the present embodiments include, but are not limited to, quantum key distribution and other forms of quantum communication, sensing (e.g., magnetometry), and cluster-state quantum computing.

### BRIEF DESCRIPTION OF THE FIGURES

FIG. 1 is a side cross-sectional view of a quantum light source, in embodiments.

FIG. 2 is a perspective view of a bullseye cavity of the quantum light source of FIG. 1.

FIG. 3 illustrates operation of the quantum light source of FIG. 1.

FIG. 4 is a side cross-sectional view of a quantum light source that is similar to the quantum light source of FIGS. 1 and 3 except that top and bottom substrates are directly bonded to each other, in an embodiment.

FIG. 5 is a side cross-sectional view of a heterostructure that may be used with the quantum light sources of FIGS. 1, 3, and 4, in embodiments.

FIG. 6A is a plot of Purcell factor versus wavelength obtained from numerical simulations of the quantum light source of FIG. 1.

FIG. 6B is a plot of the square of the absolute value of the electric field (|E|²) of a cavity mode having a Purcell factor in excess of five.

FIG. 6C is a plot of transmission through a top mirror of the quantum light source of FIG. 1 versus the number of trenches of the bullseye cavity of FIG. 2.

FIG. 6D is a plot of the transverse intensity profile of the output mode just above the top mirror.

FIG. 7 is a measured photoluminescence spectrum of a quantum dot for different voltages applied across a Schottky barrier.

FIG. 8 shows two measured photoluminescence spectra of an ensemble of quantum dot, illustrating improved photon collection when the ensemble is located inside a bullseye cavity.

### DETAILED DESCRIPTION

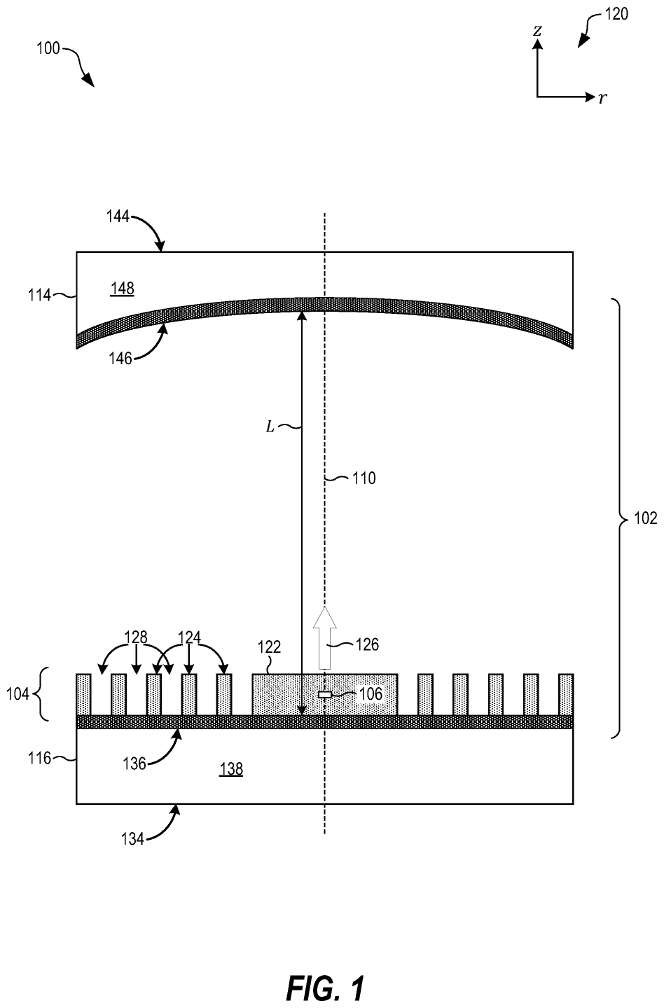

FIG. 1 is a side cross-sectional view of a quantum light source 100. The quantum light source 100 includes a quantum emitter 106 that is located within a composite optical cavity that is formed from a bullseye cavity 104 and Fabry-Perot cavity 102 that are spatially overlapped. The quantum emitter 106 is located on, or near, an optical axis 110 that lies parallel to a z axis of a coordinate system 120. For clarity herein, the terms “axial” and “longitudinal” refer to directions parallel to the optical axis 110 while the terms “radial” and “transverse” refer to directions perpendicular to the optical axis 110. The Fabry-Perot cavity 102 is also referred to as a “top-down” cavity.

The Fabry-Perot cavity 102 is formed from a top mirror 114 and a bottom mirror 116 that face each other to form longitudinal modes therebetween. In FIG. 1, the top mirror 114 has a reflective front face 146 formed on a top substrate 148. Similarly, the bottom mirror 116 has a reflective front face 136 formed on a bottom substrate 138. Thus, the Fabry-Perot cavity 102 is formed from the reflective front faces 136 and 146. The reflective front faces 136 and 146 are axially separated by a cavity length L. Light of wavelength A can excite a longitudinal mode when the cavity length L equals an integer multiple of ½. The optical axis 110 extends between the transverse centers of the reflective faces 136 and 146.

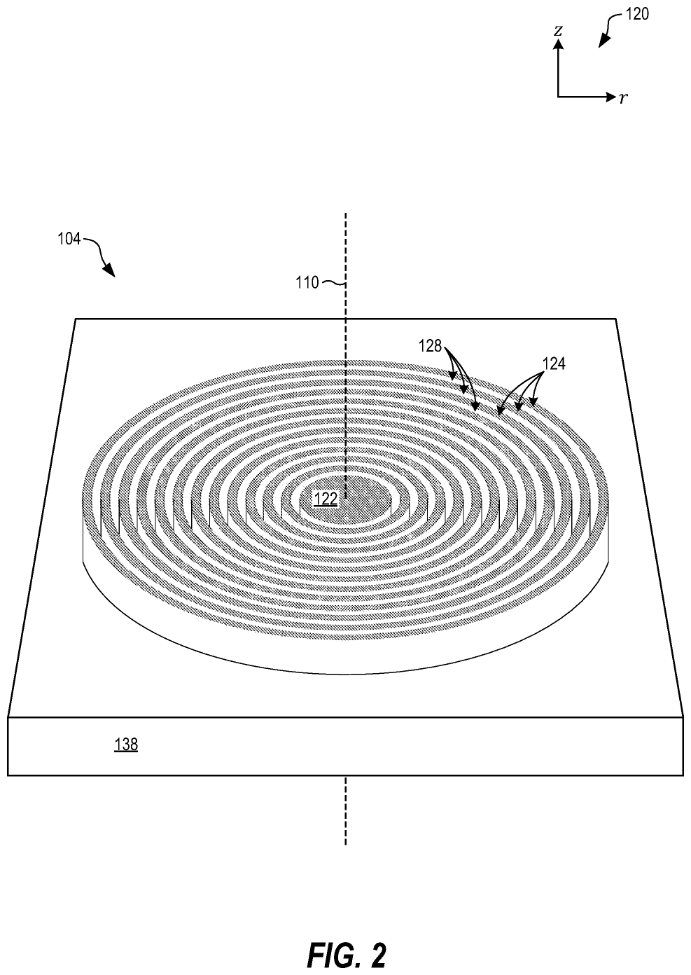

FIG. 2 is a perspective view of the bullseye cavity 104 that illustrates the structure of the bullseye cavity 104 in more detail. The quantum emitter 106 is embedded within or on a center disk 122 formed from a first material having a first refractive index n₁. The center disk 122 is centered on the optical axis 110. Encircling the center disk 122 is an alternating sequence of rings that are concentric with the center disk 122. This alternating sequence includes a first subset of rings 124 formed from the first material and a second subset of rings 128 formed from a second material having a second refractive index n₂ that is different than the first refractive index n₁. The radially innermost ring of the alternating sequence is formed from the second material (i.e., one of the rings 128). For clarity in FIGS. 1 and 2, not all of the rings 124 and 128 are labeled. Also for clarity, the quantum emitter 106 is not shown in FIG. 2.

The bullseye cavity 104 therefore lies flat in a plane that is perpendicular to the optical axis 110. The bullseye cavity 104 is also located within the Fabry-Perot cavity 102 in that it is located axially between the front reflective faces 136 and 146. The radial widths of the rings 124 and 128 are selected, based on the refractive indices n₁ and n₂, such that the bullseye cavity 104 inhibits spontaneous emission of the quantum emitter 106 in all radial directions encircling the quantum emitter 106. Thus, with the bullseye cavity 104, spontaneous emission from the quantum emitter 106 is preferably emitted along the optical axis 110. The bottom mirror 116 reflects spontaneous emission emitted downward (i.e., in the −z direction). With this reflection, all spontaneous emission from the quantum emitter 106 propagates vertically upward, as indicated in FIG. 1 by an emission direction 126.

In free space (i.e., the absence of the bullseye cavity 104 and Fabry-Perot cavity 102), the quantum emitter 106 may emit spontaneously in all directions. Spontaneous emission that is emitted radially outward (i.e., in directions that are primarily perpendicular to the optical axis 110) is likely to be lost in this case, as compared to spontaneous emission that is emitted axially (i.e., in directions that are primarily along the optical axis 110). Accordingly, the bullseye cavity 104 reduces wasted light, thereby increasing the efficiency with which it is collected and thereby used for the application at hand.

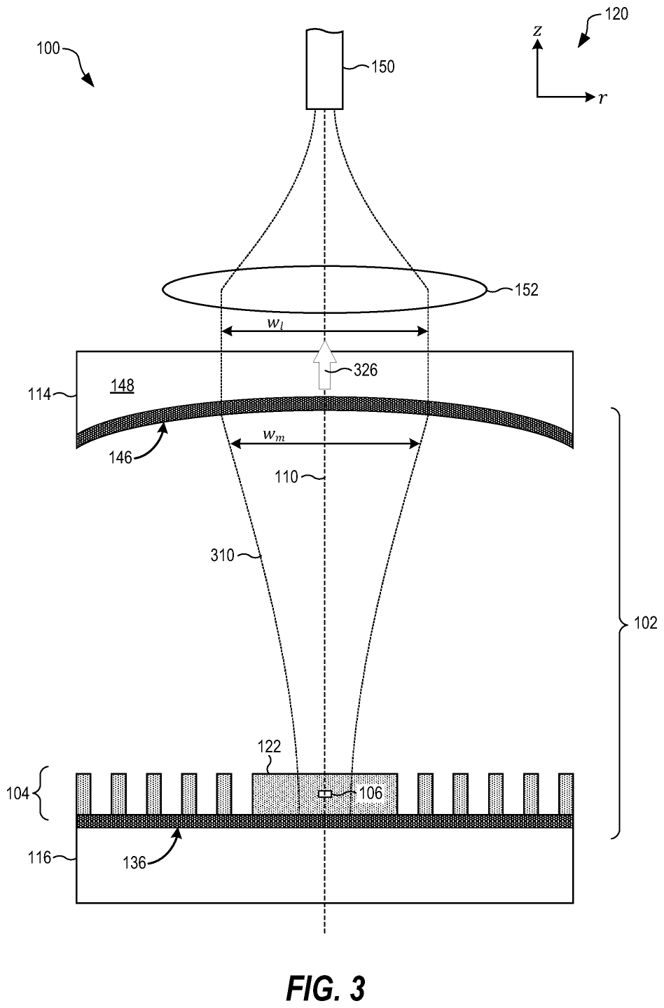

FIG. 3 illustrates operation of the quantum light source 100. With the quantum emitter 106 located within the Fabry-Perot cavity 102, spontaneous emission from the quantum emitter 106 strongly couples to the longitudinal modes of the Fabry-Perot cavity 102 when the wavelength λ of the spontaneous emission is resonant with the Fabry-Perot cavity 102. The bullseye cavity 104 increases coupling to the longitudinal modes, enhancing the probability that a spontaneously emitted photon excites a longitudinal mode.

Due to the finite Q or finesse of the Fabry-Perot cavity 102, energy in a longitudinal mode eventually leaks out of the Fabry-Perot cavity 102. In FIG. 1, leakage light 326 is transmitted through the top mirror 114. However, light can also leak through the bottom mirror 116. It is assumed that intracavity losses due to diffraction (e.g., surface scatter off of the reflective front faces 136 and 146) and bulk absorption (e.g., the center disk 122) are minimal compared to leakage through the top mirror 114 (or bottom mirror 116). In embodiments, the reflectivity of the bottom mirror 116 (i.e., the reflective face 136) is higher than that of the top mirror 114 (i.e., the reflective face 146) such that light leaking out of the Fabry-Perot cavity 102 is preferentially transmitted through the top mirror 114, as opposed to the bottom mirror 116. A rear face 144 of the top mirror 114 may be anti-reflection coated to enhance transmission of the leakage light 326 through the top substrate 148. For the same reason, a rear face 134 of the bottom mirror 116 may also be anti-reflection coated.

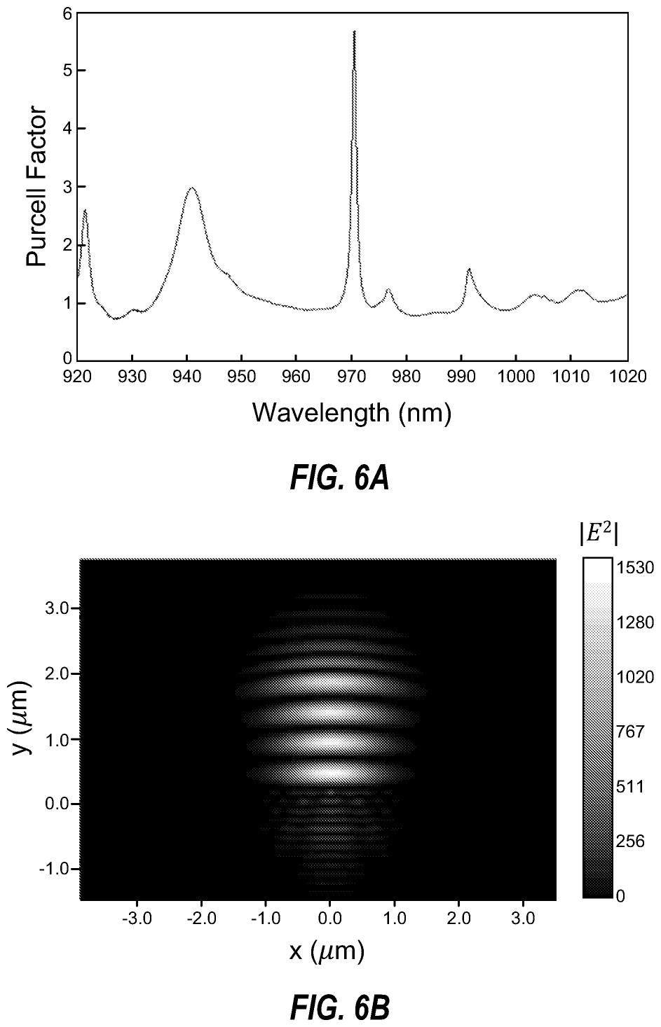

Leakage light 326 is a traveling wave that propagates vertically upward, away from the Fabry-Perot cavity 102. Leakage light 326 has a transverse field profile that is determined by the excited mode of the Fabry-Perot cavity 102. Specifically, each longitudinal mode of the Fabry-Perot cavity 102 has several transverse modes. Herein, it is assumed that only the lowest-order transverse mode is excited. This lowest-order transverse mode has a transverse intensity profile that is approximately described by a two-dimensional Gaussian profile (e.g., see FIG. 6C). As indicated by a mode envelope 310, the width wₘ of this Gaussian profile varies with axial position z inside the Fabry-Perot cavity 102. Accordingly, the transverse intensity profile of the leakage light 326 can be approximated by a Gaussian profile whose width wₗ is equal to the width wₘ of the mode envelope 310 at the top mirror 114.

Thus, the Fabry-Perot cavity 102 not only helps to direct spontaneous emission from the quantum emitter 106 into the vertical direction, but it also spatially filters this spontaneous emission into a collimated Gaussian beam that can be efficiently (i.e., with low loss) coupled into an optical fiber 150, an optical waveguide, another optical cavity, or any other type of optical component. This coupling is shown in FIG. 3 with a lens 152 that focuses the leakage light 326 into an end face of the optical fiber 150. To increase transmission, the end face of the optical fiber 150 and surfaces of the lens 152 may be anti-reflection coated. While FIG. 3 shows the lens 152 as a bi-convex lens, the lens 152 may alternatively be an aspheric lens, a microscope objective, or another type of lens or lens assembly known in the art.

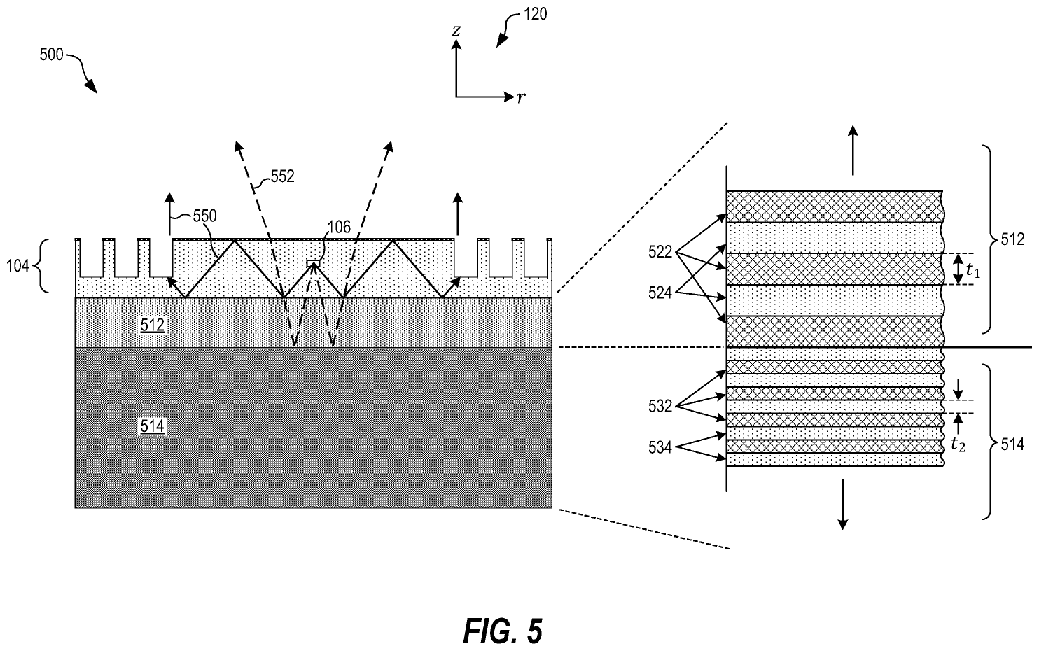

In the example of FIGS. 1 and 3, the bottom mirror 116 and bullseye cavity 104 form part of a semiconductor heterostructure. Such integration can be used to simplify the fabrication of these components. In this example, the reflective front face 136 may be a dielectric stack forming a distributed Bragg reflector (e.g., see FIG. 5). However, the reflective front face 136 may alternatively be a sub-wavelength reflector (e.g., an optical metasurface), a metallic reflector, a photonic crystal, or another type of reflector or mirror known in the art. Similarly, the reflective front face 146 of the top mirror 114 may be a dielectric mirror, sub-wavelength reflector, photonic crystal, metallic mirror, or another type of reflector or mirror.

In the example of FIGS. 1 and 3, the bottom mirror 116 is planar and the top mirror 114 is concave. The Fabry-Perot cavity 102 may have a half-confocal geometry in which the top mirror 114 has a radius of curvature R and the cavity length L is approximately equal to R/2. This geometry ensures that the Fabry-Perot cavity 102 is stable. However, the cavity length L need not be exactly equal to R/2, provided that the Fabry-Perot cavity 102 is stable. The Fabry-Perot cavity 102 may alternatively be configured with another type of geometry (e.g., full confocal, concentric, concave-convex, etc.). To prevent losses due to diffraction off the edges of the center disk 122, the center disk 122 may have a diameter much larger than the width wₘ at the center disk 122.

In the example of FIGS. 1 and 3, the bullseye cavity 104 and quantum emitter 106 are axially located adjacent to the bottom mirror 116. In this case the bullseye cavity 104 and bottom mirror 116 physically contact each other. Furthermore, due to the half-confocal geometry, the bullseye cavity 104 and quantum emitter 106 are located near the waist of the Fabry-Perot cavity 102. However, the bullseye cavity 104 and quantum emitter 106 may be located elsewhere in the Fabry-Perot cavity 102 (e.g., near the top mirror 114 or in-between the mirrors 114 and 116). In these cases, the bullseye cavity 104 and quantum emitter 106 need not directly contact the bottom mirror 116.

The quantum emitter 106 may be any kind of quantum emitter or non-linear emitter known in the art. In some embodiments, the quantum emitter 106 is a quantum dot. The quantum dot may be a semiconductor quantum dot made from indium arsenide (InAs), indium gallium arsenide (InGaAs), gallium arsenide (GaAs), gallium nitride (GaN), or another kind of semiconductor material. In other embodiments, the quantum emitter 106 is a point defect in a crystalline lattice. For example, the point defect may be a nitrogen-vacancy (NV) center in diamond, or another kind of color center that can act as a quantum emitter. In other embodiments, the quantum emitter 106 is a trapped neutral atom, trapped molecule, or trapped ion (either molecular or atomic). In these embodiments, the quantum emitter 106 may be trapped (e.g., with an optical dipole trap) inside the Fabry-Perot cavity 102 and bullseye cavity 104. In this case, the center disk 122 may be vacuum. In other embodiments, the quantum emitter 106 is a molecule (e.g., a molecular qubit) embedded in a host matrix.

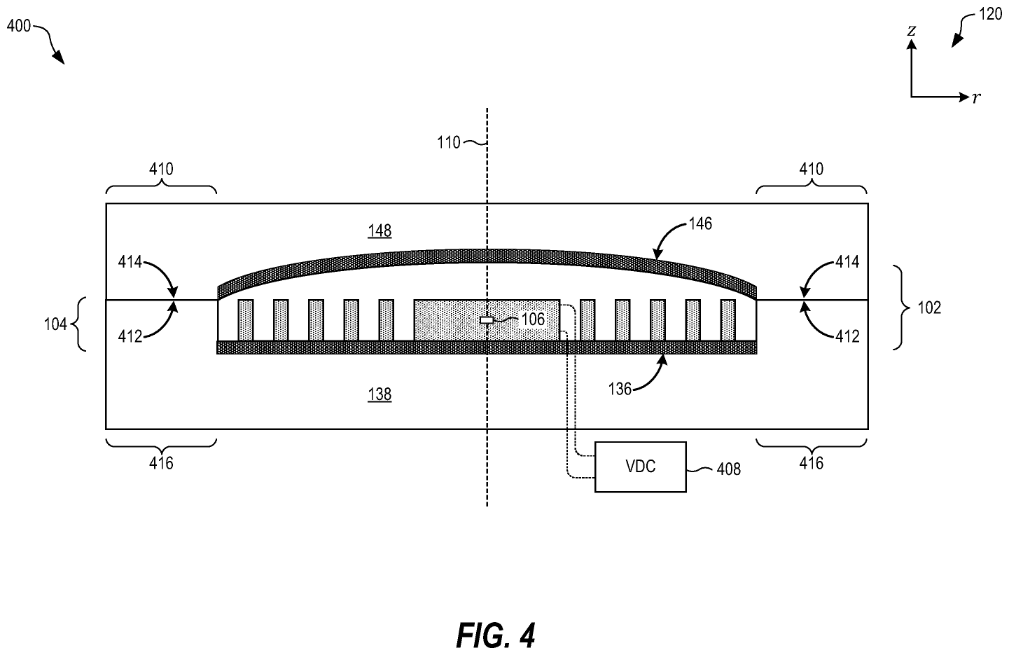

FIG. 4 is a side cross-sectional view of a quantum light source 400 that is similar to the quantum light source 100 of FIGS. 1 and 3 except that the top substrate 148 and bottom substrate 138 are directly bonded to each other in the region encircling the composite cavity. Specifically, the top substrate 148 forms a radially distant region 410 that encircles the reflective front face 146. The radially distant region 410 has a bottom surface 414 that may lie axially at or below (i.e., in the −z direction) the reflective front face 146. Similarly, the bottom substrate 138 has a radially distant region 416 that encircles the reflective front face 136 and the bullseye cavity 104. The radially distant region 416 has an upper surface 412 that may lie axially at or above the bullseye cavity 104 such that it directly contacts the bottom surface 414. In one embodiment, the upper surface 412 and bottom surface 414 directly contact each other continuously around the composite cavity.

The upper surface 412 and bottom surface 414 may be bonded to each other, such as optical contact bonding or anodic bonding. Alternatively, the upper surface 412 and bottom surface 414 may be adhered to each other using epoxy, solder, or another type of adhesive known in the art. Advantageously, bonding the surfaces 412 and 414 together may be performed using wafer-bonding techniques known in the art. These techniques allow the quantum light source 400 to be manufactured in large-scale quantities.

With the substrates 138 and 148 directly bonded to each other, the cavity length L cannot be adjusted by axially translating the mirrors 114 and 116. However, there are other ways to ensure that spontaneous emission from the quantum emitter 106 is resonant with the Fabry-Perot cavity 102. For example, when the quantum emitter 106 is a quantum dot, the quantum dot may be embedded within an undoped intrinsic semiconductor region of a p-i-n junction. A voltage applied across the junction (e.g., see voltage source 408 in FIG. 4) can be used to tune the wavelength λ of the spontaneous emission. In another example, the front reflective face 136 is metal in direct contact with the quantum dot to form a Schottky barrier. A voltage applied across the Schottky barrier can also be used to vary the wavelength A.

In other embodiments, the wavelength λ of the spontaneous emission is changed via strain or pressure tuning. Such tuning may be implemented, for example, with a piezoelectric transducer affixed to the quantum emitter 106 or the center disk 122. In other embodiments, a piezoelectric transducer affixed or bonded to one or both of the substrates 138 and 148 can be used to slightly change the cavity length L by stressing one or both of the mirrors 114 and 116. Another method to vary the wavelength/or change the resonant frequencies of the Fabry-Perot cavity 102 may be used without departing from the scope hereof.

FIG. 5 is a side cross-sectional view of a heterostructure 500 in which the bullseye cavity 104 lies over an oblique distributed Bragg reflector (DBR) mirror 512, which in turn lies over a normal DBR mirror 514. The oblique DBR mirror 512 is formed from a stack of layers 522 and 524 with alternating refractive indices. Specifically, the layers 522 are formed from a first material having a first refractive index while the layers 524 are formed from a second material having a second refractive index different from first refractive index. Similarly, the normal DBR mirror 514 is formed from a stack of layers 532 and 534 that have alternative refractive indices. In the example of FIG. 5, the layers 532 are formed from the first material while the layers 534 are formed from the second material. For clarity in FIG. 5, not all of the layers 522 and 524 are shown. Similarly, not all of the layers 532 and 534 are shown.

Each of the layers 522 and 524 has a first optical thickness t₁ while each of the layers 532 and 534 has a second optical thickness t₂ that is less than the first optical thickness t₁. The greater thickness of the layers 522 and 524, as compared to the layers 532 and 534, means that for spontaneous emission of wavelength λ, the oblique DBR mirror 512 will reflect spontaneous emission emitted from the quantum emitter 106 at oblique angles relative to the optical axis 110. Such spontaneous emission is identified in FIG. 5 as oblique light 550. By comparison, spontaneous emission emitted from the quantum emitter 106 at angles that are closer to the normal direction of the DBR mirrors 512 and 514 will mostly propagate through the oblique DBR mirror 512 to reach the normal DBR mirror 514, which will reflect this spontaneous emission. Such spontaneous emission is identified in FIG. 5 as normal light 552.

The use of multiple DBR mirrors, each tailored to reflect light at different angles of incidence, help prevent the loss of oblique light 550 emitted by the quantum emitter 106, as compared to when there is only one DBR mirror configured for normal reflection. Accordingly, the heterostructure 500 can help improve the coupling of spontaneous emission out of the Fabry-Perot cavity 102. While FIG. 5 shows two DBR mirrors, the concept can be extended to three or more stacked DBR mirrors. In one embodiment, the heterostructure 500 includes one DBR mirror structure formed from layers whose thicknesses vary continuously along z. In another embodiment, the DBR mirrors 512 and 514 are physically separate from the bullseye cavity 104, thereby forming two or more distinct heterostructures.

### Numerical Simulations

To demonstrate the efficiency of the present embodiments, multiphysics simultaneous were performed of the quantum light source 100 of FIG. 1 using the heterostructure 500 of FIG. 5. To simulate the quantum emitter 106, a dipole was placed at the center of the composite cavity. Cavity parameters were adjusted to maximize the transmission, through the top mirror 114, of spontaneous emission emitted from the dipole. The following table lists the optimal values that were found for various parameters:

| Top-Down Cavity Parameters | | | Bullseye Cavity Parameters | | |
|---|---|---|---|---|---|
| Mirror Curvature | 6 | μm | Center Diameter | 1075 | nm |
| Cavity Length L | 1.83 | μm | Trench Depth | 143 | nm |

| | | | | |
|---|---|---|---|---|
| Bottom DBR Num. Layers | 47 | Trench Width | 65 | nm |
| Top DBR Num. Layers | 7 | Trench Period | 325 | nm |

| | | | |
|---|---|---|---|
| Oblique DBR Num. Layers | 2 | Num. Trenches | 30 |

For the numerical simulations, the planar bottom mirror 116 was modeled as an AlAs/GaAs DBR stack while the top mirror 114 was modeled as a Ta₂O₅/SiO₂ DBR stack. For the bullseye cavity 104 to interact more efficiently with horizontally emitted photons, two oblique DBR layers were placed directly under the layer containing the dipole (e.g., see oblique DBR mirror 512 in FIG. 5). These oblique DBR layers had a larger periodicity than the DBR layers used as the normal bottom mirror (see layers 522 and 524 versus layers 532 and 534 in FIG. 5). FIG. 6A is a plot of the Purcell factor versus wavelength, showing a cavity mode with a Purcell factor in excess of 5 at a wavelength near 970.04 nm. FIG. 6B is a plot of the square of the absolute value of the electric field (|E|²) of this particular cavity mode.

FIG. 6C is a plot of transmission through the top mirror 114 versus the number of trenches of the bullseye cavity 104. For 30 trenches, this transmission increases to 0.825, as compared to only 0.655 without the bullseye cavity 104, a 17% enhancement. FIG. 6D is a plot of the transverse intensity profile of the output mode just above the top mirror 114. As can be seen, this transverse profile is close to a Gaussian, which can be efficiently coupled into an optical waveguide (e.g., the optical fiber 150 of FIG. 3).

### Quantum Random Number Generation

One application of the present embodiments is quantum random number generation with low bias. Random numbers that are quantum-generated can be used to produce encryption keys that are harder to break, as compared to alternative encryption methods. Furthermore, the quantum light generated by the present embodiments can be tested, via Bell's inequality, to verify that no party other than the sole user possesses the keys, the ultimate level of privacy which many prior-art random number generators cannot offer [1].

Biased and shared random number strings lead to weak and breakable encryption keys. Quantum random number generators (QRNGs) have several advantages over traditional pseudo-random number generators (PRNGs) [1, 2]. First, QRNGs use processes that are inherently unpredictable, particularly related to quantum superposition. Second, entanglement between quantum particles makes these superposition states intertwined such that the generated randomness can be certified to be unbiased to a degree of confidence that cannot be achieved with PRNGs. Third, a test based on Bell's inequality can be performed to verify that the QRNG generated “fresh” random numbers (i.e., not prerecorded) and that these random numbers are private only to the user. Fourth, the randomness generation can be device-independent, which means that the privacy verification test also shows that the components of the QRNG are not communicating the generated numbers to a third party (e.g., an eavesdropper or hacker). QRNGs with this capability are called “certified.” To date, certified QRNGs have been demonstrated with low-efficiency spontaneous entanglement generation, which has limited the random-number generation rates to 1000 bits per second (e.g., see reference [2]). Furthermore, to verify the privacy of the randomness with current schemes, a distance of hundreds of meters between the entanglement generation and measurement stations is needed.

The quantum light source of the present embodiments (e.g., the quantum light source 100) may be used as a single-photon source (SPS) for a private, unbiased, high-speed QRNG. In general, a QRNG repeats an operating cycle to generate a stream of random bits. For each operating cycle, the QRNG performs the following steps: (i) the SPS generates a single photon (i.e., a single-photon state), (ii) the single photon is collected and routed to a detector, and (iii) the single photon is detected. The QRNG is “efficient” when each of these three steps is performed with high probability (i.e., near unity).

Regarding step (i), quantum dots are the most efficient sources for generating on-demand single photons. For example, quantum dots made from indium arsenide (InAs) have been shown to generate single photons upon excitation (i.e., on demand) at gigahertz rates and with probabilities approaching unity [3]. However, other types of quantum dots (e.g., GaAs) and quantum emitters (e.g., NV centers in diamond) may be used for the SPS.

Regarding step (ii), quantum emitters may be placed inside an optical cavity to increase collection probability. In free space, quantum emitters typically emit photons uniformly in all directions (i.e., 4× steradians), which can be challenging to collect using conventional optics like lenses and mirrors. The optical cavity changes the spatial distribution of the emitted photons, increasing the probability that each emitted photon couples to a specific well-defined mode of the optical cavity. In turn, the cavity mode can be coupled with high probability into a useful path, such as a traveling mode of a waveguide (e.g., optical fiber) which transports the photon to the detector. The placement of a quantum emitter inside an optical cavity also utilizes the Purcell effect to increase the spontaneous emission rate of the quantum emitter, as compared to its spontaneous emission rate in free space. The Purcell effect therefore increases the rate at which single photons, and therefore random numbers, can be generated.

Regarding step (iii), superconducting nanowire single-photon detectors are the most efficient detectors of single photons [4].

The present embodiments improve QRNG efficiency by increasing the collection probability of step (ii). Specifically, the composite cavity of the present embodiments (i.e., the spatially overlapped Fabry-Perot cavity 102 and bullseye cavity 104) guides single photons from a quantum dot, or another type of emitter, into a single-mode fiber more efficiently than other SPSs (>75% versus 57%). The resulting efficiency of the QRNG can surpass the threshold for generating private randomness with low bias through quantum routing and the laws of quantum mechanics (e.g., superposition and entanglement).

Private randomness generation with low bias has been previously demonstrated with probabilistic sources, albeit with low rates and bulky setups that require distances up to hundreds of meters [1]. The present embodiments overcome these hurdles with a tabletop QRNG device that can generate private randomness at rates useful for encryption protocols. The technology not only results in a source of randomness with unique properties, but it can also serve as long-range links for a quantum network and connect quantum computers to exponentially increase their processing power.

An efficient SPS can create a superposition state on a beam splitter which can be measured at different stations using homodyne detection [6]. This homodyne detection can be used to perform a Bell test with the SPS, generating private randomness with rates dramatically faster than current solutions by at least 100-fold. Additionally, the high speed of such devices enables both the entanglement source and measurement stations to be housed in a single tabletop box, or even on a single integrated device [7], a chip-scale certified QRNG.

Such a QD-cavity system is not only a deterministic SPS, but it can also be used as an on-demand entangled photon pair source [8]. On-demand sources of single and entangled photons are the backbone of quantum networking, used for connecting and entangling distant quantum processors to each other or executing secure quantum communication protocols [9, 10]. As such, the quantum light source of the present embodiments may be used for the quantum internet [11].

To create a high-speed SPS, two approaches have been explored in the prior art. The first approach is to use heralded spontaneous down conversion processes to generate pairs of photons (called signal and idler photons). Each idler photon is sent to a single-photon detector to herald the existence of the signal photon upon a detector click. To suppress multiphoton generation, the probability of generating a heralded single photon using this method must be small (e.g., <0.1). Multiple sources can be used simultaneously to increase the probability of generating a heralded single photon. The output of the source that resulted in photon generation can then be switched to the output of the device. However, the switching loss and complications arising from using multiple sources that generate photons with similar characteristics limit the ability of these sources to generate single photons efficiently while keeping the multiphoton processes suppressed.

The second approach is to excite a two-level system, which then decays and emits a photon [3]. Such systems emit only a single photon upon excitation. Therefore, multiphoton generation is readily suppressed. Trapped atoms [13], ions [14], and defect centers in materials such as diamond [15] and silicon [16] have been proposed for this method. However, these systems are too slow to decay which results in a low single-photon rate. In the case of defect centers, their decay does not always result in an optical photon.

Some of the present embodiments utilize quantum dots as a two-level system that results in high-speed and efficient photon emission upon excitation [3]. For example, InAs quantum dots can be grown on a GaAs substrate using molecular beam epitaxy, resulting in quantum-dot wafers with low defect counts [9]. Such quantum dots are the most efficient SPSs, capable of emitting a photon within nanoseconds of excitation and with a probability as high as 96% [3].

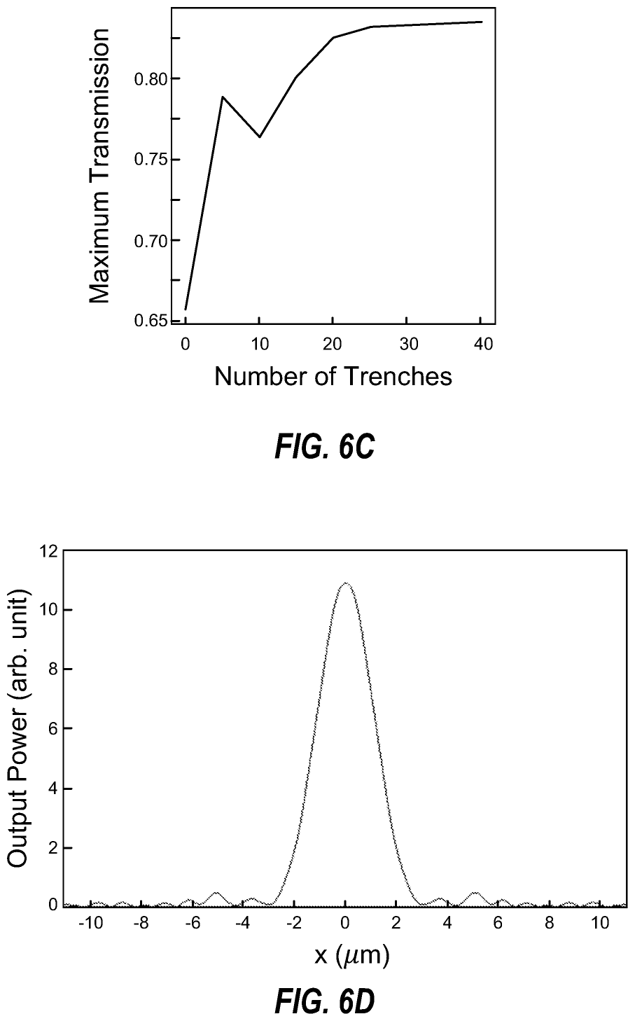

Deterministically preparing the charge states of a quantum dot is an important task for achieving a high emission probability at a single emission frequency/wavelength [17]. One way to deterministically control the charge state is to fabricate a Schottky barrier around the quantum dot. For certain values of a voltage applied across this Schottky barrier, the quantum dot is deterministically initialized into one of several charge states. This is shown in FIG. 7, which is a measured photoluminescence spectrum of a quantum dot for different voltages applied across a Schottky barrier. Each bright horizontal line indicates a different charge state. FIG. 7 shows that a quantum dot can be initialized into a specific charge state. In addition, the slope of the horizontal lines indicate that the emission frequency of the quantum dot can be tuned over a small range (e.g., less than 1 nm) by changing the voltage. Another way to initialize a quantum dot into a specific charge state and vary its emission frequency is via electrical control of a p-i-n junction within which the quantum dot is embedded.

To use these quantum dots for an on-demand SPS, the photons must be generated in a single polarization, a single frequency, and a spatial mode which can couple efficiently into a single-mode optical fiber. This coupling is performed with the composite optical cavity of the present embodiments.

The bullseye cavity (e.g., see the bullseye cavity 104 of FIGS. 1 and 2) may be formed from circular trenches of different radii that are etched into the surface of the sample, with a quantum dot located at the center [5]. These trenches ensure that the light emitted horizontally to the sample surface is guided upwards. The top-down cavity (e.g., see the Fabry-Perot cavity 102 of FIG. 1) is formed from a DBR mirror underneath the quantum dot and a concave mirror on top. The concave mirror may be fabricated on a fused silica substrate with a DBR on top [3]. As shown in FIG. 4, the two substrates may be wafer-bonded together. While this results in losing the ability to tune the cavity frequency, the quantum dot can instead be tuned, for example, using the Schottky barrier to bring it in resonance with the cavity.

The top-down cavity has been previously used for the record-high SPS efficiency of 57% [3]. However, 14% of the light in that experiment was not coupled to the desired mode due to the horizontal emission of the quantum dot. The bullseye cavity reduces this lost light by inhibiting spontaneous emission in the sideways (i.e., radial) directions. The composite cavity of the present embodiments combines the strengths of the top-down Fabry-Perot cavity and the bullseye cavity to further enhance photon emission into an optical mode that is well-matched with a single-mode optical fiber.

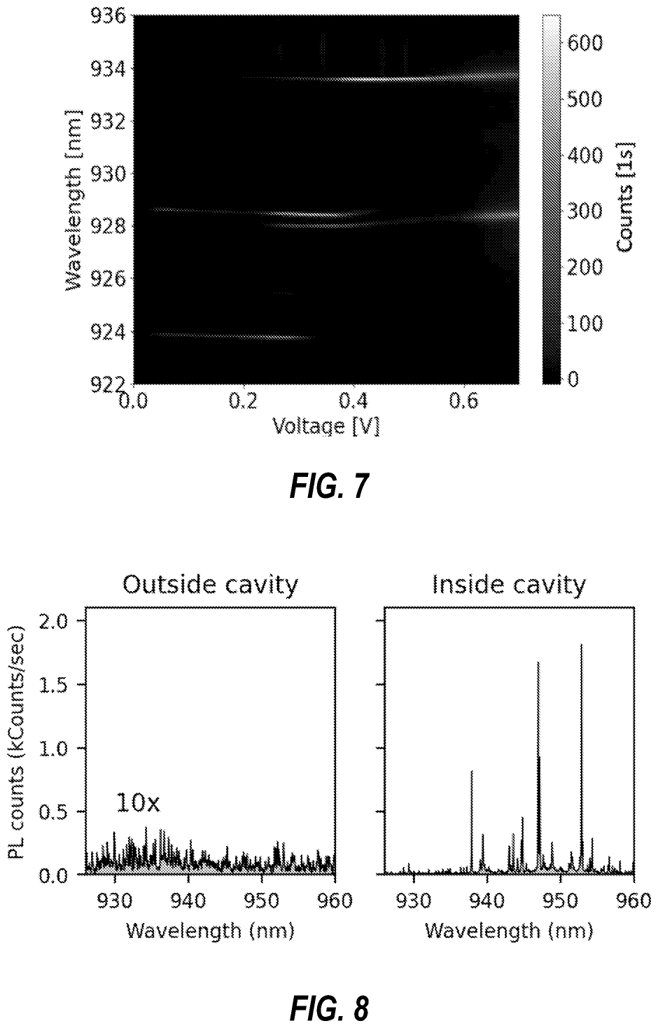

Bullseye cavities have improved photon collection from quantum dots, by a factor of ten, by guiding the photons that are emitted into the substrate vertically (e.g., see FIG. 5), as well as better mode-matching with optical fibers [18]. Unlike previous demonstrations [5], these cavities do not require suspended structures, and instead use a carefully designed DBR under the quantum dot, which is compatible with the top-down cavity. This improved photon collection can be seen in FIG. 8, which shows two measured photoluminescence spectra of an ensemble of quantum dots. In the left panel of FIG. 8, the ensemble was located outside of a bullseye cavity (i.e., no enhancement in photon collection). In the right panel of FIG. 8, the ensemble was located inside of a bullseye cavity. Note that the left panel is multiplied by a factor of ten. The photoluminescence was measured with a CCD camera, as opposed to a superconducting nanowire single-photon detector.

There are many approaches for fabricating the concave mirror of the top-down cavity (i.e., the top mirror 114 in FIG. 1). One approach is CO₂ laser ablation [3]. In this case, the concave mirrors are fabricated by shining a CO₂ laser on the silica substrate to melt the surface with curvatures as small as 10 μm. Another approach is photoresist pattern transfer [19]. In this approach, circular photoresist is patterned on the silica substrate. The photoresist is then reflowed by baking it, forming a concave shape. Finally, surfaces are etched to transfer the shape of the photoresist onto silica and remove the residual photoresist. Using this method, mirror curvatures as small as 100 μm have been demonstrated.

Efficient SPS can be used to generate certifiable quantum random numbers. The simplest way to generate a random number through a quantum process is to send a single photon into a 50/50 beam splitter. Two single-photon detectors are located at the outputs of this beam splitter. The clicks recorded by the detectors produce a series of random bits based on which detector clicks at each cycle [20]. The bias of this QRNG depends on how close the transmission/reflection of the beam splitter is to 50%, and if the transmissivity changes with fluctuations in the photon mode, such as its wavelength or polarization.

The use of quantum entanglement can further enhance this protocol with non-classical correlations between quantum states, lowering the bias drastically and adding the privateness test to the random numbers generated. The simplest photonic entangled state has two photons, each of which can exist in two modes, |0> or |1>. The overall state of the two photons is |ψ>∝|00>+|11>, which means that a measurement of the first photon immediately reveals the state of the second photon. However, these photons can be measured in a basis other than {|0>, |1>}, e.g., {|+>, |−>}, where |+>=(|0>+|1>)/\sqrt{2} and |−>=(|0>−|1>)/\sqrt{2}. The two-photon state can be rewritten in this basis as |ψ>∝|++>+|−−>, which again shows strong correlations. If the two photons are space-like separated and the measurement bases are chosen randomly, a Bell test can prove that the outcomes of the measurements show true quantum correlations (i.e., nonlocality). If the outcomes are measured faster than information about the chosen bases can travel between the two measurement stations (i.e., the speed of light), a loophole-free Bell test can result in randomness generation with biases as low as 10⁻²⁰ [1]. To put this number in perspective, achieving a similar bias with classical RNGs requires the device to first generate 1040 random numbers, impossible to achieve with even the fastest state-off-the-art RNGs within the lifetime of our universe. This low bias results in safer encryption key generation. Additionally, a Bell test indicates that the joint state measured between the two stations is a pure quantum state, meaning it has no correlations with anything outside of the stations. This leads to the proof that the generated random numbers are private to the user, and that they were freshly generated.

There are two challenges associated with certified QRNGs. The first is the strict photon transmission threshold throughout the experiment, which should exceed ˜75% [1]. Second, certified QRNGs that have been demonstrated to date have low rates of up to 1000 bits per second, due to the fact that they use spontaneous entangled photon sources which at each cycle result in a photon-pair only with less than 5% probability in order to suppress multi photon-pair events [2].

As an alternative to two-photon entangled states, a loophole-free Bell test can be performed with a single-photon state incident on a beam splitter [6]. The state of the two output ports can then be written as |ψ>∝|01>+|10>. Here, |0> indicates no photons in the port and |1> a single photon. Writing the state in this form simply means the photon is in a superposition of the two output ports. This state can be used as a single-photon entangled state, for which the measurement bases are more complicated and make use of homodyne detection to show nonlocality [6].

### Combinations of Features

Features described above as well as those claimed below may be combined in various ways without departing from the scope hereof. The following examples illustrate possible, non-limiting combinations of features and embodiments described above. It should be clear that other changes and modifications may be made to the present embodiments without departing from the spirit and scope of this invention:
(A1) A quantum light source includes a bullseye cavity, a Fabry-Perot cavity, and a quantum emitter located within both the bullseye cavity and the Fabry-Perot cavity.
(A2) In the quantum light source denoted (A1), the Fabry-Perot cavity includes first and second mirrors that face each other, the Fabry-Perot cavity defines an optical axis extending between the first and second mirrors, and the bullseye cavity lies in a plane perpendicular to the optical axis.
(A3) In the quantum light source denoted (A2), the quantum light source further includes a substrate located between the first and second mirrors, the quantum emitter being embedded within the substrate.
(A4) In either of the quantum light sources denoted (A2) and (A3), the second mirror is a dielectric mirror.
(A5) In either of the quantum light sources denoted (A2) and (A3), the second mirror is a metallic mirror.
(A6) In any of the quantum light sources denoted (A2) to (A5), the second mirror is planar.
(A7) In any of the quantum light sources denoted (A2) to (A6), the first mirror is concave.
(A8) In the quantum light source denoted (A7), the first mirror has a radius of curvature of 100 microns or less.
(A9) In any of the quantum light sources denoted (A2) to (A8), the quantum light source further includes an optical fiber having a tip positioned to receive photons that exit the Fabry-Perot cavity via the second mirror.
(A10) In any of the quantum light sources denoted (A1) to (A9), the bullseye cavity includes a center disk formed from a first material having a first refractive index. The bullseye cavity further includes an alternating sequence of concentric rings surrounding the center disk. Each of a first subset of the alternating sequence of concentric rings is formed from the first material, each of a second subset of the alternating sequence of concentric rings is formed from a second material having a second refractive index different than the first refractive index, and an innermost ring of the alternating sequence of concentric rings is formed from the second material.
(A11) In the quantum light source denoted (A10), the second material is air or vacuum.
(A12) In either of the quantum light sources denoted (A10) and (A11), the quantum emitter is embedded within the center disk.
(A13) In any of the quantum light sources denoted (A10) to (A13), the bullseye cavity includes a lower substrate of the first material. The second subset of the alternating sequence of concentric rings are trenches etched downward from a top surface of the lower substrate such that the lower substrate, after etching, forms the first subset of the alternating sequence of concentric rings.
(A14) In the quantum light source denoted (A13), the Fabry-Perot cavity includes first and second mirrors that face each other. The first mirror is a planar mirror located beneath the lower substrate. The second mirror is a concave mirror formed on an upper substrate that is located above the lower substrate.
(A15) In the quantum light source denoted (A14), the upper substrate is directly bonded to the lower substrate.
(A16) In the quantum light source denoted (A15), the upper substrate is directly bonded to the lower substrate continuously along a line that encircles the first mirror and the second mirror.
(A17) In any of the quantum light sources denoted (A1) to (A16), the quantum emitter is a point defect in a crystal.
(A18) In the quantum light source denoted (A17), the point defect is a nitrogen-vacancy center in diamond.
(A19) In any of the quantum light sources denoted (A1) to (A16), the quantum emitter is a quantum dot.
(A20) In the quantum light source denoted (A19), the quantum dot is a semiconductor quantum dot.
(A21) In the quantum light source denoted (A20), the semiconductor quantum dot is embedded within a p-i-n junction.
(A22) In the quantum light source denoted (A20), the semiconductor quantum dot forms part of a Schottky barrier.
(A23) In any of the quantum light sources denoted (A20) to (A22), the quantum dot is formed from (InAs), indium gallium arsenide (InGaAs), gallium arsenide (GaAs), or gallium nitride (GaN).
(B1) A method includes optically pumping any one of the quantum light sources denoted (A1) to (A23) to generate a single photon.
(B2) In the method denoted (B1), said optically pumping includes exciting the quantum emitter with light that is resonant with a one-photon transition of the quantum dot.
(B3) In the method denoted (B2), the quantum emitter is a quantum dot and the method further includes controlling the quantum dot, prior to said optically pumping, to put the quantum dot into a negatively charged ground state.
(B4) In the method denoted (B2), the quantum emitter is a quantum dot and the method further includes controlling the quantum dot, prior to said optically pumping, to put the quantum dot into a neutral ground state.
(B5) In the method denoted (B4), said optically pumping includes exciting the quantum dot from the neutral ground state to a lowest-energy biexcitonic state.
(B6) In the method denoted (B5), the method further includes optically driving the quantum dot to induce stimulated emission of the quantum dot from the lowest-energy biexcitonic state to an excitonic state.
(B7) In any of the methods denoted (B1) to (B6), the method further includes coupling the single photon into an optical fiber.
(C1) A method includes optically pumping any one of the quantum light sources denoted (A1) to (A23) to generate a pair of entangled photons.
(C2) In the method denoted (C1), the quantum emitter is a quantum dot and the method further includes controlling the quantum dot, prior to said optically pumping, to put the quantum dot into a neutral ground state.
(C3) In the method denoted (C2), said optically pumping includes exciting the quantum dot from the neutral ground state to a lowest-energy biexcitonic state.
(C4) In any of the methods denoted (C1) to (C3), the method further includes coupling one or both of the pair of entangled photons into an optical fiber.

Changes may be made in the above methods and systems without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

### REFERENCES

[1] P. Bierhorst et al., “Experimentally generated randomness certified by the impossibility of superluminal signals,” Nature 556, 223-226 (2018).
[2] L. K. Shalm et al., “Device-independent randomness expansion with entangled photons,” Nat. Phys. 17, 452-456 (2021).
[3] N. Tomm et al., “A bright and fast source of coherent single photons,” Nat. Nanotechnol. 16, 399-403 (2021).
[4] D. v. Reddy, D. v. Reddy, R. R. Nerem, S. W. Nam, R. P. Mirin, and V. B. Verma, “Superconducting nanowire single-photon detectors with 98% system detection efficiency at 1550 nm,” Optica 7, 1649-1653 (2020).
[5] L. Sapienza, M. Davanço, A. Badolato, and K. Srinivasan, “Nanoscale optical positioning of single quantum dots for bright and pure single-photon emission,” Nat. Commun. 6, 7833 (2015).
[6] I. S̆upić and N. Brunner, “Self-testing nonlocality without entanglement,” arXiv 2203.13171 (2022).
[7] C. McDonald, G. Moody, S. W. Nam, R. P. Mirin, J. M. Shainline, A. McCaughan, S. Buckley, and K. L. Silverman, “III-V photonic integrated circuit with waveguide-coupled light-emitting diodes and WSi superconducting single-photon detectors,” Appl. Phys. Lett. 115, 081105 (2019).
[8] J. Liu et al., “A solid-state source of strongly entangled photon pairs with high brightness and indistinguishability,” Nat. Nanotechnol. 14, 586-593 (2019).
[9] P. Imany et al., “Quantum phase modulation with acoustic cavities and quantum dots,” Optica 9, 501-504 (2022).
[10] Y. Tsuchimoto, Z. Sun, E. Togan, S. Fält, W. Wegscheider, A. Wallraff, K. Ensslin, A. Imamoğlu, and M. Kroner, “Large-bandwidth transduction between an optical single quantum-dot molecule and a superconducting resonator,” arXiv 2110.03230v1 (2021).
[11] H. J. Kimble, “The quantum internet,” Nature 453, 1023-1030 (2008).
[12] F. Kaneda and P. G. Kwiat, “High-efficiency single-photon generation via large-scale active time multiplexing,” Sci. Adv. 5 (2019).
[13] F. Ripka, H. Kübler, R. Löw, and T. Pfau, “A room-temperature single-photon source based on strongly interacting Rydberg atoms,” Science 362, 446-449 (2018).
[14] H. G. Barros, A. Stute, T. E. Northup, C. Russo, P. O. Schmidt, and R. Blatt, “Deterministic single-photon source from a single ion,” New J. Phys. 11, 103004 (2009).
[15] E. N. Knall, et al., “Efficient Source of Shaped Single Photons Based on an Integrated Diamond Nanophotonic System,” arXiv 2201.02731 (2022).
[16] S. Castelletto, “Silicon carbide single-photon sources: challenges and prospects,” Mater. Quantum. Tech. 1, 023001 (2021).
[17] A. v. Kuhlmann, J. Houel, D. Brunner, A. Ludwig, D. Reuter, A. D. Wieck, and R. J. Warburton, “A dark-field microscope for background-free detection of resonance fluorescence from single semiconductor quantum dots operating in a set-and-forget mode,” Rev. Sci. Instrum. 84, 073905 (2013).
[18] R. A. DeCrescent, Z. Wang, P. Imany, R. C. Boutelle, R. P. Mirin, and K. L. Silverman, “Semicircular dielectric gratings for strongly polarized and enhanced emission from GaAs/InAs quantum dots,” 2022 Conference on Lasers and Electro-Optics (CLEO), San Jose, CA, USA, pp. 1-2 (2022).
[19] N. Jin, C. A. McLemore, D. Mason, J. P. Hendrie, Y. Luo, M. L. Kelleher, P. Kharel, F. Quinlan, S. A. Diddams, and P. T. Rakich, “Scalable fabrication of ultrahigh-finesse micromirrors with variable geometry,” arXiv 2203.15931 (2022).
[20] Q. Luo et al., “Quantum random number generator based on single-photon emitter in gallium nitride,” Opt. Lett. 45, 4224-4227 (2020).

1. A quantum light source, comprising:
a bullseye cavity;
a Fabry-Perot cavity; and
a quantum emitter located within both the bullseye cavity and the Fabry-Perot cavity.

2. The quantum light source of claim 1, wherein:
the Fabry-Perot cavity comprises first and second mirrors that face each other, the Fabry-Perot cavity defining an optical axis extending between the first and second mirrors; and
the bullseye cavity lies in a plane perpendicular to the optical axis.

3. The quantum light source of claim 2, further comprising a substrate located between the first and second mirrors, the quantum emitter being embedded within the substrate.

4-6. (canceled)

7. The quantum light source of claim 2, the first mirror being concave and having a radius of curvature of 100 microns or less.

8. (canceled)

9. The quantum light source of claim 2, further comprising an optical fiber having a tip positioned to receive photons that exit the Fabry-Perot cavity via the second mirror.

10. The quantum light source of claim 1, the bullseye cavity comprising:
a center disk formed from a first material having a first refractive index; and
an alternating sequence of concentric rings surrounding the center disk, each of a first subset of the alternating sequence of concentric rings being formed from the first material, each of a second subset of the alternating sequence of concentric rings being formed from a second material having a second refractive index different than the first refractive index, an innermost ring of the alternating sequence of concentric rings being formed from the second material.

11. (canceled)

12. The quantum light source of claim 10, the quantum emitter being embedded within the center disk.

13. The quantum light source of claim 10, wherein:
the bullseye cavity comprises a lower substrate of the first material; and
the second subset of the alternating sequence of concentric rings are trenches etched downward from a top surface of the lower substrate such that the lower substrate, after etching, comprises the first subset of the alternating sequence of concentric rings.

14. The quantum light source of claim 13, the Fabry-Perot cavity comprising first and second mirrors that face each other, the first mirror comprising a planar mirror located beneath the lower substrate, the second mirror comprising a concave mirror formed on an upper substrate that is located above the lower substrate.

15. The quantum light source of claim 14, the upper substrate being directly bonded to the lower substrate.

16. (canceled)

17. The quantum light source of claim 1, the quantum emitter comprising a point defect in a crystal.

18. (canceled)

19. The quantum light source of claim 1, the quantum-light emitter comprising a quantum dot.

20. The quantum light source of claim 19, the quantum dot comprising a semiconductor quantum dot.

21-23. (canceled)

24. A method comprising optically pumping the quantum light source of claim 1 to generate a single photon.

25. The method of claim 24, wherein said optically pumping comprises exciting the quantum emitter with light that is resonant with a one-photon transition of the quantum emitter.

26. The method of claim 25, wherein:
the quantum emitter is a quantum dot; and
the method further comprises controlling the quantum dot, prior to said optically pumping, to put the quantum dot into a negatively charged ground state.

27. The method of claim 25, wherein:
the quantum emitter is a quantum dot; and
the method further comprises controlling the quantum dot, prior to said optically pumping, to put the quantum dot into a neutral ground state.

28-29. (canceled)

30. The method of claim 24, further comprising coupling the single photon into an optical fiber.

31. A method comprising optically pumping the quantum light source of claim 1 to generate a pair of entangled photons.

32-33. (canceled)

34. The method of claim 31, further comprising coupling one or both of the pair of entangled photons into an optical fiber.
